(19) United States
(12) Patent Application Publication
(10) Pub. No.: US 2013/0016440 A1
(43) Pub. Date: Jan. 17, 2013

(54) BASE FOR MOTOR AND HARD DISK DRIVE INCLUDING THE SAME

(71) Applicant: Tae Young CHOI, Yongin (KR)

(72) Inventor: Tae Young CHOI, Yongin (KR)

(73) Assignee: SAMSUNG ELECTRO-MECHANICS CO., LTD, Suwon (KR)

(21) Appl. No.: 13/348,109

(22) Filed: Jan. 11, 2012

(30) Foreign Application Priority Data
Jul. 14, 2011 (KR) 10-2011-0069892

(51) Int. Cl. H05K 5/03; G11B 21/02

(52) U.S. Cl. 360/75; 248/678; G9B/21.003

(57) ABSTRACT

There is provided a base for a motor, the base including: a base body having a disk disposed thereon; and an outer wall part formed on the base body to thereby define an outer edge thereof, wherein the outer wall part includes at least one cut wall part formed by cutting a predetermined region and an outer side wall part formed by bending a region other than the cut wall part.

### CROSS-REFERENCE TO RELATED APPLICATIONS

This application claims the priority of Korean Patent Application No. 10-2011-0069892 filed on Jul. 14, 2011, in the Korean Intellectual Property Office, the disclosure of which is incorporated herein by reference.

### BACKGROUND OF THE INVENTION

1. Field of the Invention

The present invention relates to a base for a motor and a hard disk drive including the same, and more particularly, to a base for a motor manufactured by pressing or forging and having an improved sealing function, and a hard disk drive including the same.

2. Description of the Related Art

A hard disk drive (HDD), an information storage device for a computer, reads data stored on a disk or writes data to the disk using a magnetic head.

In this hard disk drive, a base is installed with a head driver, that is, a head stack assembly (HSA), capable of altering a position of the magnetic relative to the disk. The magnetic head performs its function while moving to a desired position in a state in which it is suspended above a writing surface of the disk by the head driver at a predetermined height.

According to the related art, in manufacturing a base provided in the hard disk drive, a post-processing scheme of die-casting aluminum (Al) and then removing therefrom burrs or the like, generated due to the die-casting process, has been used.

However, in the die-casting scheme according to the related art, since a process of injecting molten aluminum (Al) for casting to form a substrate is performed, high temperatures and pressure are required, such that a large amount of energy is required in the process and a process time is increased.

Further, even in terms of a lifespan of a die-casting mold, there is a limitation in manufacturing a large number of bases using a single mold, and a base manufactured by the die-casting process may have poor dimensional precision.

Therefore, in order to solve defects occurring due to the die-casting process, the base has been manufactured using a pressing or forging process. However, in the case of the pressing or forging process, there is a limitation that the base can only have a uniform thickness due to characteristics of a process of bending and cutting a plate.

Further, in order to improve driving characteristics of the hard disk drive (HDD), an internal space is sealed by a sealing member adhered to an upper surface of the base and a lower surface of a cover. In this configuration, a contact area between the base and the sealing member is an important factor determining sealing characteristics.

However, in the case of manufacturing the base by the pressing or forging process, since an outer diameter and an outer width of the disk have been defined as an international standard, dimensions of an inner wall and an outer wall of the base maintained to be spaced apart from the outer diameter of the disk by a predetermined interval have also inevitably been standardized.

Under this restricted condition, in the case of manufacturing the base by the pressing or forging process, since the inner and the outer walls can only be manufactured by a bending process, an upper surface of the base can only have a circular shape, due to the inner and outer walls.

Therefore, a defect in which a contact area between the base and the sealing member in adhering the sealing member to the base is reduced occurs, such that a sealing function may be deteriorated.

Therefore, research into a technology of securing a structure having an improved sealing function by overcoming a limitation that a base can only have a uniform thickness, even in the case of manufacturing a base by a pressing or forging process, is urgently required.

### SUMMARY OF THE INVENTION

An aspect of the present invention provides a base for a motor capable of having significantly improved performance and a significantly improved lifespan by allowing an internal space thereof to be effectively sealed, even in the case of using a pressing or forging process, and a hard disk drive including the same.

According to an aspect of the present invention, there is provided a base for a motor, the base including: a base body having a disk disposed thereon; and an outer wall part formed on the base body to thereby define an outer edge thereof, wherein the outer wall part includes at least one cut wall part formed by cutting a predetermined region and an outer side wall part formed by bending a region other than the cut wall part.

The outer wall part may include an inner side wall part formed by being bent from an end portion of the base body, and the outer side wall part may be formed by bending a region other than the cut wall part from an end portion of the inner side wall part.

An upper surface of the cut wall part may be a flat surface so that a sealing part for sealing is disposed thereon at the time of coupling with the cover.

The upper surface of the cut wall part may be provided in parallel with an upper surface of the base body.

An outer side surface of the cut wall part may be disposed on the same plane as an outer side surface of the outer side wall part.

The base body may be formed by press processing.

According to another aspect of the present invention, there is provided a hard disk drive including the base for a motor as described above; a spindle motor coupled to the base for a motor to thereby rotate a disk; a head driver moving a magnetic head to a predetermined position on the disk, the magnetic head writing data to the disk and reproducing the data written on the disk; and a cover coupled to the base for a motor and including a sealing part disposed on an upper surface of the cut wall part so that an internal space of the base for a motor is sealed.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view showing a hard disk drive including a base for a motor according to an embodiment of the present invention;

FIG. 2 is a schematic cut-away perspective view showing the hard disk drive including the base for a motor according to the embodiment of the present invention but omitting a sealing part;

FIG. 3 is a schematic cross-sectional view taken along line A-A of FIG. 2; and

FIGS. 4A through 4C are schematic perspective views showing a process of manufacturing a base for a motor according to the embodiment of the present invention.

### DETAILED DESCRIPTION OF THE INVENTION

Embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, but those are construed as being included in the spirit of the present invention.

Further, like reference numerals will be used to designate like components having similar functions throughout the drawings within the scope of the present invention.

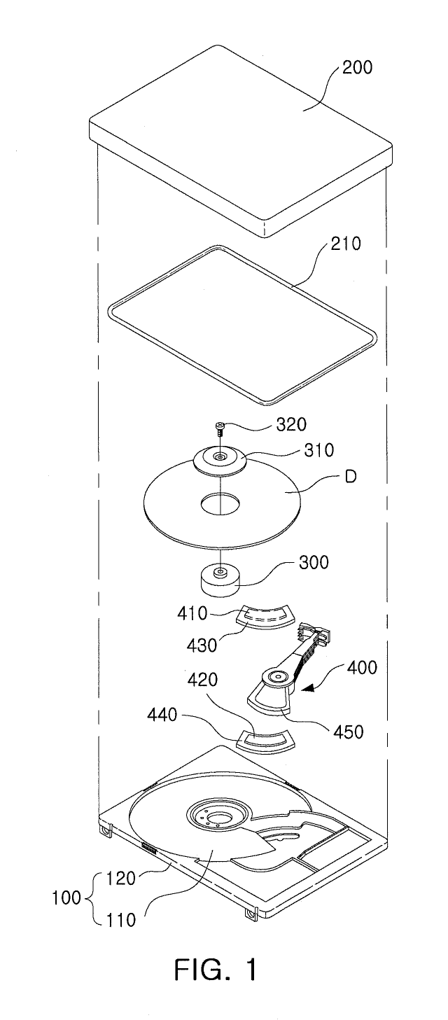

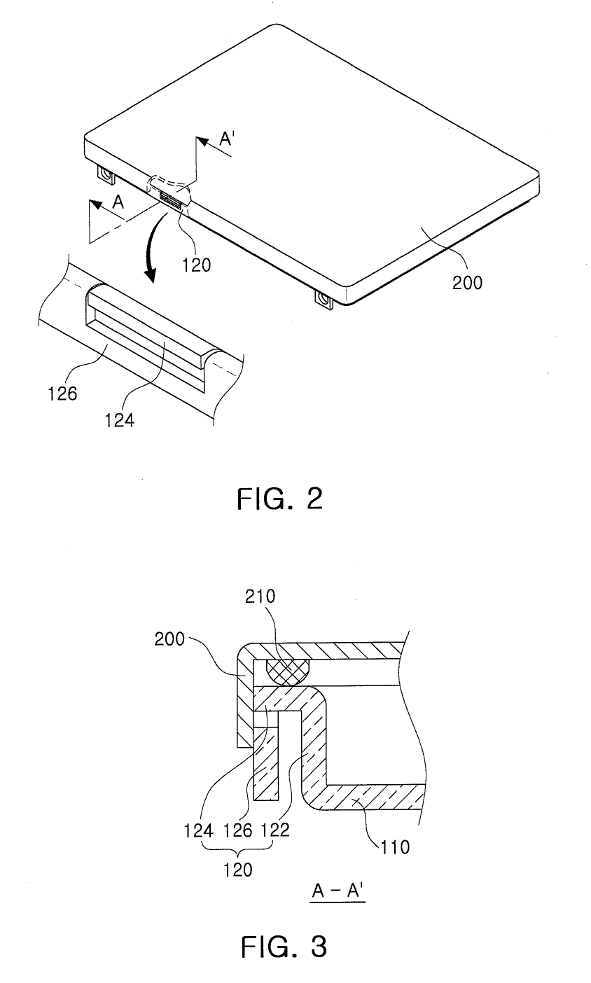

FIG. 1 is a schematic exploded perspective view showing a hard disk drive including a base for a motor according to an embodiment of the present invention; FIG. 2 is a schematic cut-away perspective view showing the hard disk drive including the base for a motor according to the embodiment of the present invention but omitting a sealing part; and FIG. 3 is a schematic cross-sectional view taken along line A-A of FIG. 2.

Referring to FIGS. 1 through 3, the hard disk drive 500 according to the embodiment of the present invention may include a base 100 for a motor (hereinafter, referred to as a “base”), a cover 200 including a sealing part 210 sealing an internal space of the base 100, and a spindle motor 300 and a head driver 400 disposed in an internal space of the base 100.

Terms with respect to directions will be first defined. An axial direction refers to a direction from an upper surface of the base 100 toward the cover 200 or a direction opposite thereto.

The base 100 may be a housing forming an appearance together with the cover 200 in the hard disk drive 500 according to the embodiment of the present invention and include a base body 110 and an outer wall part 120.

Here, the base 100 may be manufactured to have a basic shape in which it includes the base body 110 by press and forging processing and be then manufactured to have a final shape in which it includes the outer wall part 120 by bending or cutting processing, additional processing.

That is, the base 100 according to the embodiment of the present invention may be manufactured by performing a single process by the press or the forging or an additional processing on a cold rolled steel sheet (SPCC, SPCE, or the like) or a hot rolled steel sheet, unlike the post-processing scheme according to the related art in which aluminum (Al) is die-cast and a burr, or the like, generated due to the die-casting is then removed.

Therefore, the base 100 according to the embodiment of the present invention may be manufactured by a forge or pressing process to significantly reduce a process time and energy consumption. As a result, production capability may be improved.

In addition, the base body 110 may form an internal space of the base 100 therein, wherein the internal space indicates a space in which a spindle motor 300 and a head driver 400 to be described below are disposed.

The outer wall part 120 indicates an outer wall of the base 100. More specifically, the outer wall part 120 may define an outer side of the base body 110.

That is, the outer wall part 120 may be formed at an end portion of the base body 110 and include an inner side wall part 122, a cut wall part 124, and an outer side wall part 126.

The inner side wall part 122 of the outer wall part 120 may be formed by bending the end portion of the base body 110 upwardly in an axial direction, and the outer side wall part 126 may be formed by again bending the inner side wall part 122 downwardly in the axial direction at a predetermined height.

Here, a connection part between the inner side wall part 122 and the outer side wall part 126, may be a part at which the sealing part 210 sealing the internal space of the base 100 is disposed and needs to have a flat surface for increasing a contact area with the sealing part 210 provided in the cover 200 in order to significantly increase the sealing function.

Here, schematically describing standards of the base 100, most of dimensions of the base 100 have been standardized. Particularly, an outer diameter of a disk D, a width of the outer side wall parts 126, and the inner side wall part 122 maintained to be spaced apart from the outer diameter of the disk D by a predetermined interval have also been standardized.

In the case of the die-casting process according to the related art in which the outer side wall part and the inner side wall part may be formed integrally with each other, since the base may be manufactured so that an upper side wall part, which is a boundary between the outer side wall part and the inner side wall part, may have a predetermined flat surface; a sufficient surface on which the sealing part for sealing the internal space of the base is to be disposed may be secured.

However, in a case in which the base 100 is manufactured by disposing a plate shaped steel, which is a base material, that is, a cold rolled steel sheet (SPCC, SPCE, or the like) or a hot rolled steel sheet in a press mold and pressing the plate shaped steel at a predetermined pressure as in the base 100 according to the embodiment of the present invention, the base can only basically have a uniform thickness.

Therefore, in the outer wall part 120 of the base 100, the inner side wall part 122 and the outer side wall part 126 can only be formed by the bending process so as to be in accordance with the international standard as described above.

Therefore, the connection part between the inner side wall part 122 and the outer side wall part 126 can only have a round shape, and a portion of the connection part between the inner side wall part 122 and the outer side wall part 126 of the outer wall part 120 is too narrow to dispose the sealing part 210 sealing the internal space of the base 100 thereon.

In order to solve the above-mentioned defect, the outer wall part 120 of the base 100 according to the embodiment of the present invention may include the cut wall part 124 formed by cutting a predetermined area, whereby a flat surface on which the sealing part 210 is disposed may be implemented.

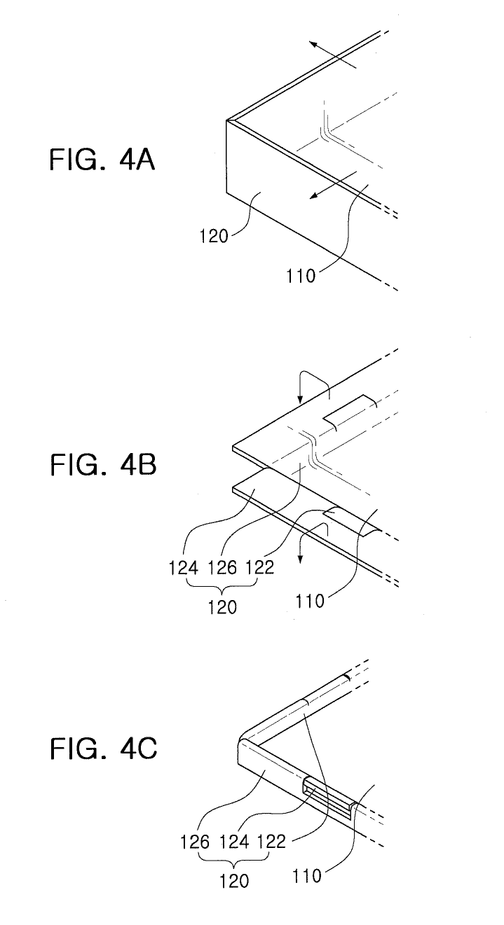

A detailed process of manufacturing the cut wall part 124 will be described below with reference to FIGS. 4A through 4C. Hereinafter, the base 100 after the cut wall part 124 is formed will be described.

As described above, the inner side wall part 122 of the outer wall part 120 may be formed by bending the end portion of the base body 110 upwardly in an axial direction, and the outer side wall part 126 may be formed by cutting a predetermined region and then bending a region other than the cut region downwardly from the end portion of the inner side wall part 122 in the axial direction.

Here, the cut predetermined region may configure the cut wall part 124. The cut wall part 124 may include the sealing part 210 disposed on an upper surface thereof for sealing at the time of coupling with the cover 200.

That is, the upper surface of the cut wall part 124 may be a flat surface so that the sealing part 210 may be firmly sealed and be in parallel with an upper surface of the base body 110 of the base 100.

In addition, an outer side surface of the cut wall part 124 may be disposed on the same plane as an outer side surface of the outer side wall part 126.

The spindle motor 300, to rotate the disk D, may be fixedly mounted at a central portion of the base body 110. The disk D, which is coupled to the spindle motor 300 to thereby rotate together with the spindle motor 300, may have a writing surface on which data is written.

Here, the spindle motor 300 may includes a clamp 310 coupled to an upper end portion thereof by a screw 320 in order to firmly fix the disk D thereto.

In addition, although FIG. 1 shows a configuration in which a single disk D is mounted on the spindle motor 300, this configuration is only an example. That is, one or more disks D may be mounted on the spindle motor 300.

In the case in which a plurality of disks D are mounted as described above, a ring shaped spacer for maintaining an interval between the disks D may be disposed between the disks D.

The head driver 400 is called a head stack assembly (HAS) and may be a component having a magnetic head mounted thereon and moving the magnetic head to a predetermined position to thereby write the data to the disk D or read the data written on the disk D.

In addition, the head driver 400 may move the magnetic head to a predetermined position of the disk D by a voice coil motor (VCM) including a coil 450 and upper and lower magnets 410 and 420.

Here, each of the upper and lower magnets 410 and 420 disposed on upper and lower portions of the coil 450 provided in the VCM may be coupled to upper and lower yokes 430 and 440 in order to increase magnetic flux density and be fixed to the base 100.

The VCM may be controlled by a servo control system and rotate the head driver 400 around a pivot axis in a direction according to the Fleming's left hand rule by interaction between a current input by the coil 450 provided in the VCM and magnetic fields formed by the upper and lower magnets 410 and 420.

Here, when an operation start command is input to the hard disk drive 500 according to the embodiment of the present invention, the disk D starts to rotate, and the VCM rotates a swing arm in a counterclockwise direction and moves the magnetic head onto the writing surface of the disk D.

On the other hand, when an operation stop command is input to the hard disk drive 500 according to the embodiment of the present invention, the VCM rotates the swing arm in a clockwise direction to thereby allow the magnetic head to deviate from the disk D.

The magnetic head deviating from the writing surface of the disk D is parked in a ramp provided outside the disk D.

Here, the ramp may space the magnetic head from the disk D by a predetermined interval in the case in which the magnetic head moves to the disk D, simultaneously with parking the magnetic head, whereby the data of the disk D may be stably read.

FIGS. 4A through 4C are schematic perspective views showing a process of manufacturing a base for a motor according to the embodiment of the present invention.

In FIGS. 4A through 4C, which are views describing a process of manufacturing the outer wall part 120 of the base 100, a specific feature of the base 100 is omitted.

The base 100 according to the embodiment of the present invention may be manufactured to have a basic shape in which it includes the base body 110 by the press processing. Here, the base 100 having the basic shape generally has a uniform thickness due to characteristics of the press processing.

Then, in order to form the outer wall part 120, an end portion of the base body 110 may be bent upwardly in the axial direction to thereby form the inner side wall part 122 of the outer wall part 120 (See FIG. 4A).

Here, the inner side wall part 122 needs to be spaced apart from the outer diameter of the disk D by a predetermined interval according to the international standard as described above.

After the inner side wall part 122 is formed, an end portion of the inner side wall part 122, that is, the part bent upwardly in the axial direction may be again bent outwardly of the base 100 at a predetermined height.

Thereafter, a predetermined region may be cut in order to form the cut wall part 124 (See FIG. 4B), and a region other than for the cut region may be then again bent downwardly in the axial direction to thereby form the outer side wall part 126 (See FIG. 4C).

However, the cutting process for forming the cut wall part 124 may be performed after the process of forming the inner side wall part 122 and before the process of bending the end portion of the inner side wall part 122.

Through the process as described above, the cut wall part 124 may be formed at a portion that is relatively too narrow to dispose the sealing part 210 thereon in the connection part between the inner side wall part 122 and the outer side wall part 126 of the outer wall part 120 formed by the bending, whereby a flat surface on which the sealing part 210 is disposed may be implemented.

Therefore, even in the case of manufacturing the base 100 by the press processing, the sealing part 210 provided in the cover 200 may be firmly adhered to the upper surface of the outer wall part 120 to improve a sealing function, whereby performance and a lifespan of the hard disk drive 500 may be significantly increased.

As set forth above, with the base for a motor and the hard disk drive including the same according to the embodiments of the present invention, the internal space of the base may be effectively sealed even in the case of using the pressing or forging process.

In addition, the base for a motor may be manufactured by the forging or pressing process to significantly reduce a process time and energy consumption, whereby the production capability may be improved.

While the present invention has been shown and described in connection with the embodiments, it will be apparent to those skilled in the art that modifications and variations can be made without departing from the spirit and scope of the invention as defined by the appended claims.

What is claimed is:

1. A base for a motor, the base comprising:
a base body having a disk disposed thereon; and
an outer wall part formed on the base body to thereby define an outer edge thereof,
the outer wall part including at least one cut wall part formed by cutting a predetermined region and an outer side wall part formed by bending a region other than the cut wall part.

2. The base of claim 1, wherein the outer wall part includes an inner side wall part formed by being bent from an end portion of the base body, and
the outer side wall part is formed by bending a region other than the cut wall part from an end portion of the inner side wall part.

3. The base of claim 1, wherein an upper surface of the cut wall part is a flat surface so that a sealing part for sealing is disposed thereon at the time of coupling with the cover.

4. The base of claim 1, wherein the upper surface of the cut wall part is in parallel with an upper surface of the base body.

5. The base of claim 1, wherein an outer side surface of the cut wall part is disposed on the same plane as an outer side surface of the outer side wall part.

6. The base of claim 1, wherein the base body is formed by press processing.

7. A hard disk drive comprising:
the base for a motor of claim 1;
a spindle motor coupled to the base for a motor to thereby rotate a disk;
a head driver moving a magnetic head to a predetermined position on the disk, the magnetic head writing data to the disk and reproducing the data written on the disk; and
a cover coupled to the base for a motor and including a sealing part disposed on an upper surface of the cut wall part so that an internal space of the base for a motor is sealed.
